(19) United States
(12) Patent Application Publication
(10) Pub. No.: US 2024/0346192 A1
(43) Pub. Date: Oct. 17, 2024

(54) FENESTRATION SELECTION AND CONFIGURATION SYSTEMS WITH GEOSPATIAL RELATED FEATURES

(71) Applicant: Andersen Corporation, Bayport, MN (US)

(72) Inventors: Katherine April Stephan Graham, Inver Grove Heights, MN (US); Jeff Lien, Clayton, WI (US); Josef Hubert Wegele, Cottage Grove, MN (US); Eric Lee Ottem, River Falls, WI (US)

(21) Appl. No.: 18/606,268

(22) Filed: Mar. 15, 2024

Related U.S. Application Data
(60) Provisional application No. 63/452,653, filed on Mar. 16, 2023.

(51) Int. Cl. G06F 30/12; G06Q 30/0601

(52) U.S. Cl. CPC G06F 30/12; G06Q 30/0621

(57) ABSTRACT

Embodiments herein relate to fenestration product selection and/or configuration systems with geospatial data related features and related methods. In an embodiment, a fenestration product configuration system is included having a control circuit, a geospatial location circuit, and a display output circuit. The fenestration product configuration system is configured to determine and/or receive information on appropriate fenestrations for a fenestration project site based in part on data from the geospatial location circuit. The display output circuit is configured to generate data for a visual display including information regarding the appropriate fenestrations. Other embodiments are also included herein.

This application claims the benefit of U.S. Provisional Application No. 63/452,653, filed Mar. 16, 2023, the content of which is herein incorporated by reference in its entirety.

### FIELD

Embodiments herein relate to fenestration product selection and/or configuration systems and methods with geospatial data related features.

### BACKGROUND

Fenestrations can include windows, patio doors, and entry doors. Fenestrations can vary widely in their performance and features. This can make it challenging to select appropriate fenestrations for a given building while complying with applicable requirements.

### SUMMARY

Embodiments herein relate to fenestration product selection and/or configuration systems and methods with geospatial data related features. In a first aspect, a fenestration product configuration system can be included having a control circuit, a geospatial location circuit, wherein the geospatial location circuit can be in signal communication with the control circuit, and a display output circuit, wherein the display output circuit can be in signal communication with the control circuit. The fenestration product configuration system can be configured to determine and/or receive information on appropriate fenestrations for a fenestration project site based in part on data from the geospatial location circuit. The display output circuit can be configured to generate data for a visual display including information regarding the appropriate fenestrations.

In a second aspect, in addition to one or more of the preceding or following aspects, or in the alternative to some aspects, the fenestration product configuration system can be configured to determine a neighborhood that the building site can be located in.

In a third aspect, in addition to one or more of the preceding or following aspects, or in the alternative to some aspects, the fenestration product configuration system can be configured to retrieve neighborhood-level fenestration product information and use the same to generate one or more fenestration product recommendations.

In a fourth aspect, in addition to one or more of the preceding or following aspects, or in the alternative to some aspects, the fenestration product configuration system can be configured to cause information regarding the neighborhood-level fenestration product information to be displayed on the visual display.

In a fifth aspect, in addition to one or more of the preceding or following aspects, or in the alternative to some aspects, the fenestration product configuration system can be configured to retrieve and display neighborhood map data.

In a sixth aspect, in addition to one or more of the preceding or following aspects, or in the alternative to some aspects, the neighborhood map data includes locations of one or more noise generating civil features.

In a seventh aspect, in addition to one or more of the preceding or following aspects, or in the alternative to some aspects, the fenestration product configuration system can be configured to retrieve neighborhood-level fenestration product style information and use the same to generate one or more fenestration product style recommendations.

In an eighth aspect, in addition to one or more of the preceding or following aspects, or in the alternative to some aspects, the fenestration product configuration system can be configured to determine applicable building code requirements for the fenestration project site based in part on data from the geospatial location circuit and appropriate fenestrations can be selected including reference to the applicable building code requirements.

In a ninth aspect, in addition to one or more of the preceding or following aspects, or in the alternative to some aspects, the fenestration product configuration system can be configured to only display fenestrations satisfying the applicable building code requirements.

In a tenth aspect, in addition to one or more of the preceding or following aspects, or in the alternative to some aspects, the fenestration product configuration system can be configured to cause information regarding the applicable building code requirements to be displayed on the visual display.

In an eleventh aspect, in addition to one or more of the preceding or following aspects, or in the alternative to some aspects, the fenestration product configuration system can be configured to accept input regarding code requirements and/or other requirement values that can be specific for a local area.

In a twelfth aspect, in addition to one or more of the preceding or following aspects, or in the alternative to some aspects, the applicable building code requirements include national and local building code requirements.

In a thirteenth aspect, in addition to one or more of the preceding or following aspects, or in the alternative to some aspects, the fenestration product configuration system can be configured to determine outdated building code requirements for the fenestration project site based in part on data from the geospatial location circuit.

In a fourteenth aspect, in addition to one or more of the preceding or following aspects, or in the alternative to some aspects, the fenestration product configuration system can be configured to determine applicable financial incentives for fenestration features based in part on data from the geospatial location circuit, and cause information regarding the applicable financial incentives to be displayed on the visual display.

In a fifteenth aspect, in addition to one or more of the preceding or following aspects, or in the alternative to some aspects, the applicable financial incentives can include at least one selected from the group consisting of energy efficiency tax credits and utility rebates.

In a sixteenth aspect, in addition to one or more of the preceding or following aspects, or in the alternative to some aspects, the fenestration product configuration system can be configured to display zone mapping impacting Energy Star ratings on the visual display.

In a seventeenth aspect, in addition to one or more of the preceding or following aspects, or in the alternative to some aspects, the fenestration product configuration system can be configured to use information regarding directionality of openings to determine the appropriate fenestrations.

In an eighteenth aspect, in addition to one or more of the preceding or following aspects, or in the alternative to some aspects, the fenestration product configuration system can be configured to use information regarding directionality of openings to determine an appropriate set of fenestrations.

In a nineteenth aspect, in addition to one or more of the preceding or following aspects, or in the alternative to some aspects, the appropriate set of fenestrations includes fenestrations differing from one another in at least one property other than fenestration size and fenestration type.

In a twentieth aspect, in addition to one or more of the preceding or following aspects, or in the alternative to some aspects, the appropriate set of fenestrations includes fenestrations differing from one another in at least one property relating to thermal performance.

In a twenty-first aspect, in addition to one or more of the preceding or following aspects, or in the alternative to some aspects, the fenestration product configuration system can be configured to estimate thermal properties of fenestrations based on in part on data from the geospatial location circuit to determine those that can be appropriate.

In a twenty-second aspect, in addition to one or more of the preceding or following aspects, or in the alternative to some aspects, the fenestration product configuration system can be configured to estimate thermal properties of fenestrations based on in part on data from the geospatial location circuit and estimate at least one solar-related value based on the directionality of openings for fenestrations to determine those that can be appropriate.

In a twenty-third aspect, in addition to one or more of the preceding or following aspects, or in the alternative to some aspects, the at least one solar-related value can include at least one selected from the group consisting of solar heat gain, visual transmittance, predicted interior electric lighting needs, and interior light intensity.

In a twenty-fourth aspect, in addition to one or more of the preceding or following aspects, or in the alternative to some aspects, the fenestration product configuration system can be configured to determine recommended fenestration performance features based at least in part on data from the geospatial location circuit and positions of fenestration openings at the fenestration project site.

In a twenty-fifth aspect, in addition to one or more of the preceding or following aspects, or in the alternative to some aspects, the recommended fenestration performance features can include at least one selected from the group consisting of number of glass panes, glass type, and glass coatings.

In a twenty-sixth aspect, in addition to one or more of the preceding or following aspects, or in the alternative to some aspects, the fenestration product configuration system can be configured to generate data regarding costs of the recommended fenestration performance features and estimated energy savings of the recommended fenestration performance features and cause information regarding the same to be displayed through the visual display.

In a twenty-seventh aspect, in addition to one or more of the preceding or following aspects, or in the alternative to some aspects, the fenestration product configuration system can be configured to access security data related to the fenestration project site based in part on data from the geospatial location circuit and form fenestration security feature recommendations based on the security data.

In a twenty-eighth aspect, in addition to one or more of the preceding or following aspects, or in the alternative to some aspects, the fenestration product configuration system can be configured to access noise data related to the fenestration project site based in part on data from the geospatial location circuit and form fenestration sound reduction feature recommendations based on the noise data.

In a twenty-ninth aspect, in addition to one or more of the preceding or following aspects, or in the alternative to some aspects, the noise data includes one or more noise generating civil features.

In a thirtieth aspect, in addition to one or more of the preceding or following aspects, or in the alternative to some aspects, the one or more noise generating civil features can include at least one selected from the group consisting of a train track, a highway, and an airport.

In a thirty-first aspect, in addition to one or more of the preceding or following aspects, or in the alternative to some aspects, the fenestration product configuration system can be configured to generate one or more verification questions about the fenestration project site and cause them to be displayed through the visual display.

In a thirty-second aspect, in addition to one or more of the preceding or following aspects, or in the alternative to some aspects, the fenestration product configuration system can be configured to generate one or more verification questions about the fenestration project site and cause them to be displayed through the visual display at a first time point prior to a site visit by a system user and generate one or more verification questions about the fenestration project site and cause them to be displayed through the visual display at a second time point during the site visit by the system user.

In a thirty-third aspect, in addition to one or more of the preceding or following aspects, or in the alternative to some aspects, the fenestration product configuration system can be configured to determine the appropriate fenestrations for the fenestration project site based in part on altitude data regarding the fenestration project site.

In a thirty-fourth aspect, in addition to one or more of the preceding or following aspects, or in the alternative to some aspects, the fenestration product configuration system can be configured to determine the appropriate fenestrations for the fenestration project site based in part on wind zone data regarding the fenestration project site.

In a thirty-fifth aspect, in addition to one or more of the preceding or following aspects, or in the alternative to some aspects, the fenestration product configuration system can be configured to determine the appropriate fenestrations for the fenestration project site based in part on fire safety data regarding the fenestration project site.

In a thirty-sixth aspect, in addition to one or more of the preceding or following aspects, or in the alternative to some aspects, the fenestration product configuration system can be configured to determine the appropriate fenestrations for the fenestration project site based in part on wind driven rain data regarding the fenestration project site.

In a thirty-seventh aspect, in addition to one or more of the preceding or following aspects, or in the alternative to some aspects, the fenestration product configuration system can be configured to determine the appropriate fenestrations for the fenestration project site based in part on extreme weather data specific for the fenestration project site.

In a thirty-eighth aspect, in addition to one or more of the preceding or following aspects, or in the alternative to some aspects, the appropriate fenestrations can include at least one selected from the group consisting of windows, patio doors, and entry doors.

In a thirty-ninth aspect, in addition to one or more of the preceding or following aspects, or in the alternative to some aspects, wherein data for the visual display including information regarding the appropriate fenestrations can be dependent on the role identity of a system user.

In a fortieth aspect, in addition to one or more of the preceding or following aspects, or in the alternative to some aspects, the role identity can include at least one selected from the group consisting of a customer, a fenestration sales consultant, an architect, a building contractor, a building inspector, and a third-party validator.

In a forty-first aspect, in addition to one or more of the preceding or following aspects, or in the alternative to some aspects, the display output circuit can be configured to generate data for a visual display including a plan or perspective view of fenestrations at the fenestration project site along with a superimposed direction of highest solar exposure.

In a forty-second aspect, in addition to one or more of the preceding or following aspects, or in the alternative to some aspects, the display output circuit can be configured to display ray tracing to illustrate how sunlight will vary throughout the year at the fenestration project site.

In a forty-third aspect, in addition to one or more of the preceding or following aspects, or in the alternative to some aspects, can further include a photodetector, wherein the photodetector can be in electronic communication with the control circuit, and wherein the photodetector generates a signal regarding light intensity at a discrete location within the fenestration project site.

In a forty-fourth aspect, in addition to one or more of the preceding or following aspects, or in the alternative to some aspects, can further include a visual display, wherein the visual display can be configured to receive data from the display output circuit.

In a forty-fifth aspect, in addition to one or more of the preceding or following aspects, or in the alternative to some aspects, the fenestration product configuration system can be configured to receive user input regarding one or more selected fenestrations.

In a forty-sixth aspect, in addition to one or more of the preceding or following aspects, or in the alternative to some aspects, the fenestration product configuration system can be configured to generate a code clearance report based on the one or more selected fenestrations and data from the geospatial location circuit.

In a forty-seventh aspect, in addition to one or more of the preceding or following aspects, or in the alternative to some aspects, the code clearance report flags the one or more selected fenestrations not meeting code requirements specific for the fenestration project site.

In a forty-eighth aspect, in addition to one or more of the preceding or following aspects, or in the alternative to some aspects, the geospatial location circuit can be configured to generate and/or receive a signal regarding a present geolocation.

In a forty-ninth aspect, in addition to one or more of the preceding or following aspects, or in the alternative to some aspects, the geospatial location circuit can be configured to receive a signal regarding a present geolocation from a secondary device.

In a fiftieth aspect, in addition to one or more of the preceding or following aspects, or in the alternative to some aspects, the fenestration product configuration system can be further configured to determine or receive input regarding a fenestration height above grade.

In a fifty-first aspect, in addition to one or more of the preceding or following aspects, or in the alternative to some aspects, the fenestration product configuration system can be configured to calculate energy costs using at least one of energy rates and predominant heating types for the fenestration project site.

In a fifty-second aspect, a method of determining fenestrations for a fenestration project site can be included. The method can include determining and/or receiving information on appropriate fenestrations for the fenestration project site based in part on data from a geospatial location circuit and generating data for a visual display including information regarding the appropriate fenestrations.

In a fifty-third aspect, in addition to one or more of the preceding or following aspects, or in the alternative to some aspects, the method can further include determining a neighborhood that the building site can be located in.

In a fifty-fourth aspect, in addition to one or more of the preceding or following aspects, or in the alternative to some aspects, the method can further include retrieving neighborhood-level fenestration product information and using the same to generate one or more fenestration product recommendations.

In a fifty-fifth aspect, in addition to one or more of the preceding or following aspects, or in the alternative to some aspects, the method can further include causing information regarding the neighborhood-level fenestration product information to be displayed on the visual display.

In a fifty-sixth aspect, in addition to one or more of the preceding or following aspects, or in the alternative to some aspects, the method can further include retrieving and display neighborhood map data.

In a fifty-seventh aspect, in addition to one or more of the preceding or following aspects, or in the alternative to some aspects, the method can further include retrieving neighborhood-level fenestration product style information and use the same to generate one or more fenestration product style recommendations.

In a fifty-eighth aspect, in addition to one or more of the preceding or following aspects, or in the alternative to some aspects, the method can further include determining applicable building code requirements for the fenestration project site based in part on data from the geospatial location circuit.

In a fifty-ninth aspect, in addition to one or more of the preceding or following aspects, or in the alternative to some aspects, can further include only displaying fenestrations satisfying applicable building code requirements.

In a sixtieth aspect, in addition to one or more of the preceding or following aspects, or in the alternative to some aspects, the method can further include causing information regarding the applicable building code requirements to be displayed on the visual display.

In a sixty-first aspect, in addition to one or more of the preceding or following aspects, or in the alternative to some aspects, the method can further include accepting input regarding code requirements and/or other requirement values that can be specific for a local area.

In a sixty-second aspect, in addition to one or more of the preceding or following aspects, or in the alternative to some aspects, the method can further include determining outdated building code requirements for the fenestration project site based in part on data from the geospatial location circuit.

In a sixty-third aspect, in addition to one or more of the preceding or following aspects, or in the alternative to some aspects, the method can further include determining applicable financial incentives for fenestration features based in part on data from the geospatial location circuit and causing information regarding the applicable financial incentives to be displayed on the visual display.

In a sixty-fourth aspect, in addition to one or more of the preceding or following aspects, or in the alternative to some aspects, the method can further include displaying zone mapping impacting Energy Star ratings on the visual display.

In a sixty-fifth aspect, in addition to one or more of the preceding or following aspects, or in the alternative to some aspects, the method can further include using information regarding directionality of openings to determine the appropriate fenestrations.

In a sixty-sixth aspect, in addition to one or more of the preceding or following aspects, or in the alternative to some aspects, the method can further include using information regarding directionality of openings to determine an appropriate set of fenestrations.

In a sixty-seventh aspect, in addition to one or more of the preceding or following aspects, or in the alternative to some aspects, the method can further include estimating thermal properties of fenestrations based on in part on data from the geospatial location circuit to determine those that can be appropriate.

In a sixty-eighth aspect, in addition to one or more of the preceding or following aspects, or in the alternative to some aspects, the method can further include estimating thermal properties of fenestrations based on in part on data from the geospatial location circuit and estimate at least one solar-related value based on the directionality of openings for fenestrations to determine those that can be appropriate.

In a sixty-ninth aspect, in addition to one or more of the preceding or following aspects, or in the alternative to some aspects, the method can further include determining recommended fenestration performance features based at least in part on data from the geospatial location circuit and positions of fenestration openings at the fenestration project site.

In a seventieth aspect, in addition to one or more of the preceding or following aspects, or in the alternative to some aspects, the method can further include generating data regarding costs of recommended fenestration performance features and estimated energy savings of the recommended fenestration performance features and causing information regarding the same to be displayed through the visual display.

In a seventy-first aspect, in addition to one or more of the preceding or following aspects, or in the alternative to some aspects, the method can further include accessing security data related to the fenestration project site based in part on data from the geospatial location circuit and forming fenestration security feature recommendations based on the security data.

In a seventy-second aspect, in addition to one or more of the preceding or following aspects, or in the alternative to some aspects, the method can further include accessing noise data related to the fenestration project site based in part on data from the geospatial location circuit and forming fenestration sound reduction feature recommendations based on the noise data.

In a seventy-third aspect, in addition to one or more of the preceding or following aspects, or in the alternative to some aspects, the method can further include generating one or more verification questions about the fenestration project site and causing them to be displayed through the visual display.

In a seventy-fourth aspect, in addition to one or more of the preceding or following aspects, or in the alternative to some aspects, the method can further include generating one or more verification questions about the fenestration project site and causing them to be displayed through the visual display at a first time point prior to a site visit by a system user and generating one or more verification questions about the fenestration project site and cause them to be displayed through the visual display at a second time point during the site visit by the system user.

In a seventy-fifth aspect, in addition to one or more of the preceding or following aspects, or in the alternative to some aspects, the method can further include determining the appropriate fenestrations for the fenestration project site based in part on altitude data regarding the fenestration project site.

In a seventy-sixth aspect, in addition to one or more of the preceding or following aspects, or in the alternative to some aspects, the method can further include determining the appropriate fenestrations for the fenestration project site based in part on wind zone data regarding the fenestration project site.

In a seventy-seventh aspect, in addition to one or more of the preceding or following aspects, or in the alternative to some aspects, the method can further include determining the appropriate fenestrations for the fenestration project site based in part on fire safety data regarding the fenestration project site.

In a seventy-eighth aspect, in addition to one or more of the preceding or following aspects, or in the alternative to some aspects, the method can further include determining the appropriate fenestrations for the fenestration project site based in part on wind driven rain data regarding the fenestration project site.

In a seventy-ninth aspect, in addition to one or more of the preceding or following aspects, or in the alternative to some aspects, the method can further include determining the appropriate fenestrations for the fenestration project site based in part on extreme weather data specific for the fenestration project site.

In an eightieth aspect, in addition to one or more of the preceding or following aspects, or in the alternative to some aspects, the method can further include generating data for a visual display including a plan or perspective view of fenestrations at the fenestration project site along with a superimposed direction of highest solar exposure.

In an eighty-first aspect, in addition to one or more of the preceding or following aspects, or in the alternative to some aspects, the method can further include displaying ray tracing to illustrate how sunlight will vary throughout the year at the fenestration project site.

In an eighty-second aspect, in addition to one or more of the preceding or following aspects, or in the alternative to some aspects, the method can further include receiving user input regarding one or more selected fenestrations.

In an eighty-third aspect, in addition to one or more of the preceding or following aspects, or in the alternative to some aspects, the method can further include generating a code clearance report based on one or more selected fenestrations and data from the geospatial location circuit.

In an eighty-fourth aspect, in addition to one or more of the preceding or following aspects, or in the alternative to some aspects, the method can further include generating and/or receiving a signal regarding a present geolocation.

In an eighty-fifth aspect, in addition to one or more of the preceding or following aspects, or in the alternative to some aspects, the method can further include receiving a signal regarding a present geolocation from a secondary device.

In an eighty-sixth aspect, in addition to one or more of the preceding or following aspects, or in the alternative to some aspects, the method can further include determining or receiving input regarding a fenestration height above grade.

In an eighty-seventh aspect, in addition to one or more of the preceding or following aspects, or in the alternative to some aspects, the method can further include calculating energy costs using at least one of energy rates and predominant heating types for the fenestration project site.

This summary is an overview of some of the teachings of the present application and is not intended to be an exclusive or exhaustive treatment of the present subject matter. Further details are found in the detailed description and appended claims. Other aspects will be apparent to persons skilled in the art upon reading and understanding the following detailed description and viewing the drawings that form a part thereof, each of which is not to be taken in a limiting sense. The scope herein is defined by the appended claims and their legal equivalents.

### BRIEF DESCRIPTION OF THE FIGURES

Aspects may be more completely understood in connection with the following figures (FIGS.), in which:

FIG. 1 is a schematic view illustrating a fenestration project site in a neighborhood in accordance with various embodiments herein.

FIG. 2 is a schematic view of a system component in accordance with various embodiments herein.

FIG. 3 is a schematic view of a system in accordance with various embodiments herein.

FIG. 4 is a schematic view of a system component in accordance with various embodiments herein.

FIG. 5 is a schematic view of neighborhoods in accordance with various embodiments herein.

FIG. 6 is a climate zone map in accordance with various embodiments herein.

FIG. 7 is a schematic view of a neighborhood and noise-generating civil features in accordance with various embodiments herein.

FIG. 8 is a block view of system components in accordance with various embodiments herein.

While embodiments are susceptible to various modifications and alternative forms, specifics thereof have been shown by way of example and drawings, and will be described in detail. It should be understood, however, that the scope herein is not limited to the particular aspects described. On the contrary, the intention is to cover modifications, equivalents, and alternatives falling within the spirit and scope herein.

### DETAILED DESCRIPTION

There are many types of fenestrations with many different options providing for different performance, different appearance, different safety features, and the like. As a result, selecting appropriate fenestrations for a particular structure at a particular site can be a challenging and time-consuming experience. However, systems herein can utilize geospatial location data along with other types of data to provide information on appropriate and/or recommended fenestrations for a particular fenestration project site. For example, a fenestration product configuration system is included herein having a control circuit and a geospatial location circuit and a display output circuit. The geospatial location circuit can generate and/or receive geospatial location data (such as geospatial location coordinates and/or other geospatial location data) regarding a fenestration project site. The fenestration product configuration system can be configured to determine and/or receive information on appropriate fenestrations for a fenestration project site based in part on data from the geospatial location circuit. The display output circuit can be configured to generate data for a visual display including information regarding the appropriate fenestrations and/or the fenestration project site.

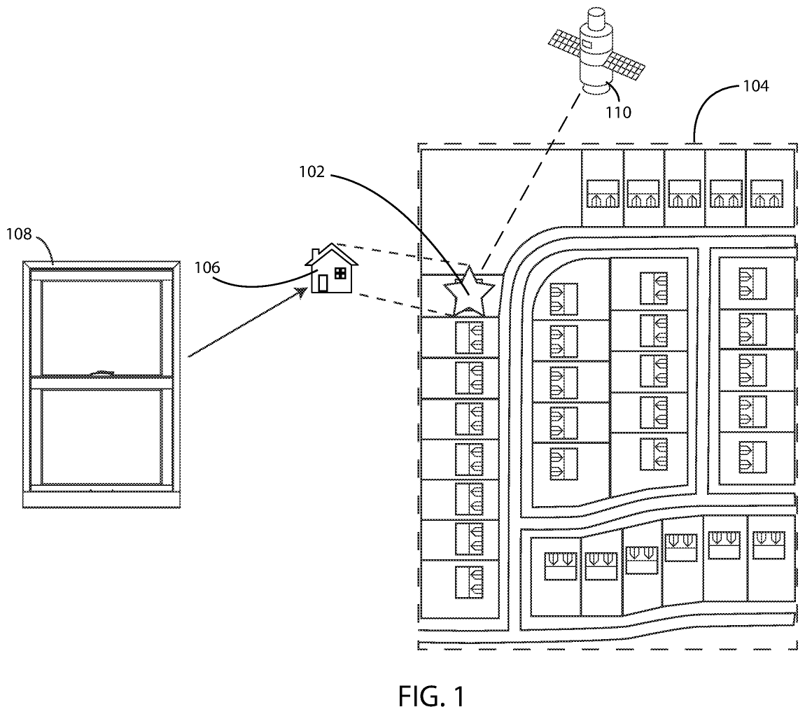

Referring now to FIG. 1, a schematic view illustrating a fenestration project site 102 in a neighborhood 104 is shown in accordance with various embodiments herein. The fenestration project site 102 includes a building 106, which could be of various types (single family home, multi-tenant residential building, commercial building, light-commercial building etc.) The building 106 includes a fenestration 108, such as a window. The building 106 can include multiple fenestrations of various types such as multiple windows, patio doors, and entry doors.

The building 106 can be disposed at a particular geospatial location, which can be determined using a geolocation circuit. In some embodiments, the geolocation circuit can receive a signal from a satellite 110 (such as with a GPS satellite signal) containing or otherwise allowing the system to determine geolocation data such as geolocation coordinate or other geolocation data. However, it will be appreciated that geolocation circuits herein can also obtain geospatial location data from other types of devices, such as a secondary device, a high-accuracy geolocation device, or the like.

The geospatial location of the building 106 dictates many factors including, but not limited to, applicable building codes, climate, probability of severe weather events, wind zone, proximity to various civil features, eligibility for energy efficiency related rebates or credits, type of energy used for heating and/or cooling, neighborhood homeowner association covenants, and the like. These factors can, in turn, influence what fenestrations and/or fenestration types or features are appropriate and/or recommended for the building 106. As such, systems herein can determine and/or receive information on appropriate fenestrations for a fenestration project site based in part on geospatial location data.

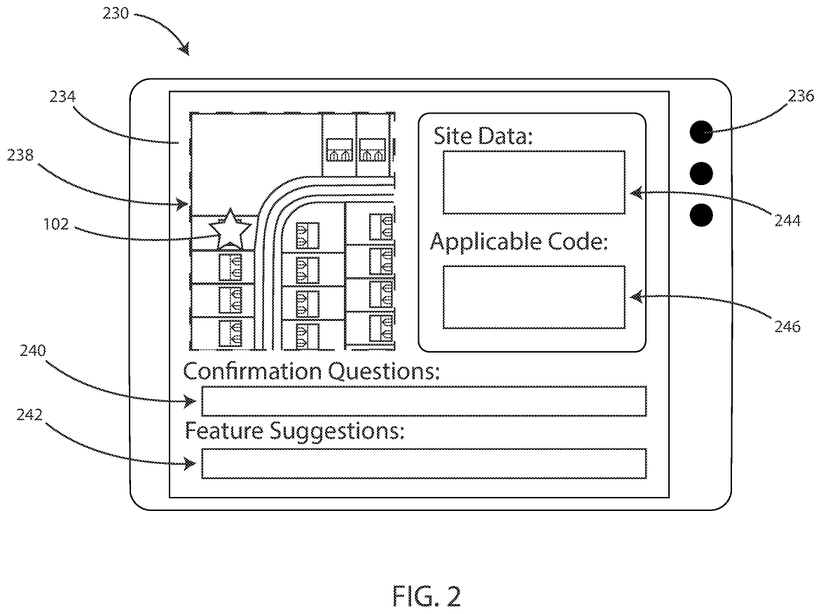

Systems herein can include a device with a visual display to output information and/or can be configured to generate visual display data that is ultimately displayed on another device. Referring now to FIG. 2, a schematic view of an exemplary user input and display unit 230 is shown in accordance with various embodiments herein. In some embodiments, the user input and display unit 230 is a handheld device. However, in other embodiments, the user input and display unit 230 can be non-handheld. The user input and display unit 230 includes a visual display 234. In various embodiments, the visual display 234 can be configured to receive data from a display output circuit.

The handheld device 232 can receive user input. In some embodiments, the visual display 234 can be a touch screen to receive user input. In some embodiments, the handheld device 232 includes input buttons 236. The handheld device 232 can receive user input of various types. In various embodiments, the fenestration product configuration system can be configured to receive user input regarding selections of one or more fenestrations and/or fenestration features.

In this example, the visual display 234 includes neighborhood map data 238, which can also include the fenestration project site 102. The visual display 234 also includes site data 244. Site data 244 can include various pieces of information including, but not limited to, site address, homeowner name, number and/or type of existing fenestrations, window glass area, building square footage, current fenestration performance levels, conditions at the site (such as climate, weather conditions, altitude, sun exposure, and the like). In some embodiments, site data 244 can be gathered with reference to database based on the site geolocation and/or the site address. For example, a query can be generated and issued to a database or API including such site data. In some embodiments, site data 244 can be gathered through user input, such as user input that may be input into the handheld device 232 and/or user input that maybe provided by a building owner of other individual (either in advance of or at the time of a site visit).

In some embodiments, the visual display 234 can present one or more queries. For example, the visual display 234 can display one or more confirmation questions 240. Confirmation questions 240 can be posed so that the system can confirm various facts regarding the geospatial location, the fenestration project site 102, the building 106, and/or various aspects regarding one of these. In some embodiments, confirmation questions 240 can be directed to site data 244 so as to confirm the accuracy of the same.

Thus, in various embodiments, the fenestration product configuration system can be configured to generate one or more verification questions about the fenestration project site 102 and cause them to be displayed through the visual display 234.

In some embodiments, queries can be configured to be presented to a system or device user at different time points. For example, the fenestration product configuration system can be configured to generate one or more queries about the fenestration project site 102 and cause them to be displayed through the visual display 234 at a first time point (which could be prior to a site visit by a system user) and then generate one or more queries about the fenestration project site 102 and cause them to be displayed through the visual display 234 at a second time point (such as during and/or after a site visit by the system user). The first time point and second time point can be separated by minutes (such as 5, 10, 15, 20 or more minutes) or even hours. In this manner, queries can be presented when relevant and the system can avoid possibly overwhelming the system user and/or a building owner by presenting too many queries at a time.

The visual display 234 also includes product feature suggestions 242. For example, product feature suggestions 242 for windows can include one or more of number of glass panes (e.g., dual pane glass, triple pane glass, etc.), glass type, glass coatings, and the like. The product feature suggestions 242 can be customized to be appropriate for the fenestration project site 102. For example, some geolocations will benefit from triple pane glass far more than others based on climate, sun exposure, and the like. As such, in some embodiments, triple pane glass is only recommended as a product feature when data regarding the fenestration project site 102 indicates that the building owner would derive a significant benefit from installing triple pane glass windows.

In some embodiments, product feature suggestions 242 and/or appropriate fenestration suggestions can be configured to be presented to a system or device user at different time points. For example, the fenestration product configuration system can be configured to generate one or more suggestions and cause them to be displayed through the visual display 234 at a first time point (which could be prior to a site visit by a system user) and then generate one or more suggestions and cause them to be displayed through the visual display 234 at a second time point (such as during and/or after a site visit by the system user). The first time point and second time point can be separated by minutes (such as 5, 10, 15, 20 or more minutes) or even hours. In this manner, suggestions can be presented when relevant and the system can avoid possibly overwhelming the system user and/or a building owner by presenting too many suggestions at a time.

The visual display 234 can also include code data 246, such as applicable building code requirements. In various embodiments, the applicable building code requirements can include national, state, and/or local building code requirements. Building code requirements can include various types of requirements including structural requirements, energy efficiency requirements, and the like. In some embodiments, code data can include requirements for tempered glass, Turtle Glass, recycled material content, and the like. In various embodiments, the fenestration product configuration system can be configured to cause information regarding the applicable building code requirements to be displayed on the visual display 234. In various embodiments, the fenestration product configuration system can be configured to accept input regarding code requirements and/or other requirement values that are specific for a local area. Code data 246 can be stored by the system, such as in a database and/or in working memory. Code data 246 can be accessed by the system using a query issued to a database and/or an API providing information regarding the same. By way of example, in some embodiments, the system can access a commercially available API such as the ICC CODE CONNECT API which can include, for example, fire, building, and mechanical codes, amongst others, or another similar API. In some embodiments, code data 246 can be input by a system user and stored. In addition, where there are multiple potentially applicable code requirements, the version to be used can be specified by the system user through user input for use with appropriate product recommendations.

In various embodiments, the fenestration product configuration system can be configured to determine outdated building code requirements for the fenestration project site 102 based in part on data from the geospatial location circuit. Outdated building code data can be accessed by issuing a query to a database and/or an API. In some embodiments, outdated building code data can be input by a system user and stored for later use. In some embodiments, information regarding outdated building code requirements can be displayed on the visual display 234. In some embodiments, the system can be configured to identify at least one change in the building code data impacting the structure at the fenestration project site. For example, in this manner, the system user and/or a homeowner can be educated on how the code requirements have changed over time to appreciate why fenestrations that previously met code requirements may no longer meet current code requirements. In some embodiments, the system can further calculate the advantages (including quantitative advantages and/or qualitative advantages) of updating the building components. Quantitative and/or qualitative advantages can include, but are not limited to, energy efficiency benefits, costs savings benefits, comfort aspects (thermal or visual), and the like.

In various embodiments, the fenestration product configuration system can be configured to determine applicable financial incentives for fenestration 108 features based in part on data from the geospatial location circuit, and cause information regarding the applicable financial incentives to be displayed on the visual display 234. In various embodiments, the applicable financial incentives can include at least one including at least one of energy efficiency tax credits and rebates from utility companies or other program sources. For example, the system can use geospatial location data regarding the project site to look up applicable financial incentive data stored in a database or otherwise accessible through an API or a website that the system can interface with programmatically. In some embodiments, the system can be configured to access, use, and/or display information regarding voluntary sustainability/environmental programs such as PassiveHaus, LEED, or the like.

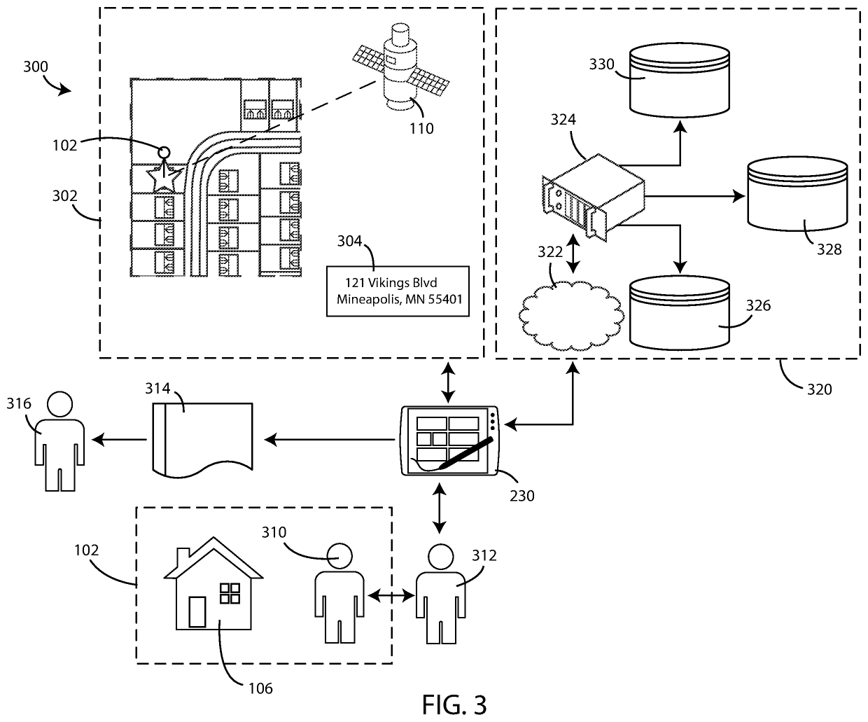

It will be appreciated that systems herein can include various different components and subsystems. Referring now to FIG. 3, a schematic view of a system 300 is shown in accordance with various embodiments herein. FIG. 3 shows geolocation determination related components 302, a remote computing architecture 320, and a fenestration project site 102.

At the fenestration project site 102, a building 106 is shown along with a product consultant 312 and a customer 310. In some embodiments, the product consultant 312 can be the system operator/user. However, in some embodiments, the system can also be configured for use directly by the customer 310.

The product consultant 312 and/or the customer 310 can interface with the system through a user input and display unit 230, which can be a dedicated device, a tablet computing device, a mobile computing device, a smartphone, a computer workstation, or the like. The user input and display unit 230 can be used to receive inputs from the product consultant 312 and/or the customer 310 as well as display information to the same. In various embodiments, the user input and display unit 230 can be mobile so that this part of the system can be brought to the fenestration project site 102. Further details of exemplary user input and display units 230 are provided below.

In some embodiments, the product consultant 312 (and/or another type of system user) may interface with the system while at or near the fenestration project site 102. However, in other cases, the product consultant 312 (and/or another type of system user) may interface with the system while remote from the fenestration project site 102. Further, while in some cases the product consultant 312 (and/or another type of system user) can interface with the system using a user input and display unit 230, in other embodiments the product consultant 312 (and/or another type of system user) can interface with the system using a computing device such as a desktop or laptop computer, a tablet computing device, a smartphone, or the like.

The building 106 can be of various types. For example, the building 106 can be a residential building, a commercial building (including light commercial), or the like. The building 106 can include a plurality of fenestrations thereon. Fenestrations herein can include fenestrations of all types including, but not limited to, windows, doors (including patio doors and entry doors), and the like. In the context of a fenestration replacement scenario, a number of the fenestrations could be candidates for replacement. In the context of new construction, many fenestrations will typically be installed. The system 300 herein can be configured to determine the specific performance requirements for each fenestration (as the requirements could vary by individual fenestration on a particular building) on the building 106 as well as guide selection of fenestration units that meet the performance requirements.

The geolocation determination related components 302 can be used to determine a geolocation of the building (“a determined geolocation”) into which fenestration units will be installed. In some embodiments, the geolocation determination related components 302 can include a geolocation circuit of the system, described below in greater detail. In some embodiments, the geolocation circuit can include and/or can be in electronic communication with a satellite signal receiver so that the geolocation circuit can determine geolocation based on signals from a satellite 110. The geolocation circuit can be part of a user input and display unit 230 that can be taken to the building site and the geolocation can be determined based on satellite signals. In other instances, a system user, such as a product consultant 312 can enter an address 304 into the user input and display unit 230 or another device and the address 304 can be used to derive a geolocation (such as geospatial coordinates). In some embodiments the address can be submitted to the cloud 322 via an address as a query (in JSON or another format such as XML) to a geolocation API (such as the Google Geocoding API) and the geolocation can be obtained via a response (in JSON or another format such as XML).

Beyond a product consultant, system users herein can include, but are not limited to, building contractors, building project sales professionals, architects, building inspectors, building owners, building project customers, and the like.

The remote architecture 320 can include various components that are accessed through and/or disposed in the cloud 322. As such, while FIG. 3 shows components separate from the cloud 322, it will be appreciated that these components can be within the cloud 322 or accessed through the cloud 322. The remote architecture 320 can include one or more servers 324 that can be real or virtual. The remote architecture 320 can include one or more databases. For example, the databases can include a location-specific conditions database 326, a building code database 328, and a product characteristic database 330, amongst others.

Using the building geolocation obtained (e.g., the determined geolocation), the system 300 can look up conditions at the site of the building 106 in the location-specific conditions database 326. Such conditions can be a key element in determining the required performance levels for fenestration units on the building 106. However, the local conditions are not the only factor in determining required performance levels for the fenestration units on the building 106. As such, the system 300 can be configured to receive an input from a system user regarding the building 106 and fenestration locations therein and determine a required performance level for one or more fenestrations of the building 106 based on the input from the system user and the geolocation of the building 106. For example, the product consultant 312 can enter various pieces of information that can be used to determine performance requirements for individual fenestration units on the building 106 into the user input and display unit 230.

In various embodiments, the fenestration product configuration system can be configured to determine applicable building code requirements for the fenestration project site 102 based in part on data from the geospatial location circuit. Appropriate fenestrations can be selected including reference to the applicable building code requirements. The building code database 328 can store data allowing the system to determine a required level of performance for one or more fenestrations of the building based on the input from the system user and the geolocation of the building. Other pieces of data can also be stored in the building code database 328 including other information required by building codes, or other sources of reference information for calculating required performance levels.

Compliance with building codes is typically ensured through a construction permitting process. A permit must initially be obtained for the work to be done and then, after the work has been completed, an inspection must be completed by a building inspector 316 who inspects details of the project to ensure that building code and other requirements have been met. Inspection can be a tedious process and requires information on the requirements that must be met (e.g., performance requirements) as well as information on the details of the project that has been completed including fenestration units that have been installed and their actual or rated performance levels. In various embodiments herein, the system 300 can case the inspection process by creating a regulatory output 314 that can be provided to, or otherwise shared with, the building inspector 316 or another representative of the applicable regulatory authority. The regulatory output 314 can be used to conveniently provide information on the required performance levels for fenestrations on the building as well as the actual or rated performance levels of fenestrations that have been installed.

Similarly, in various embodiments, the fenestration product configuration system can be configured to generate a performance and attribute summary report which may be used in some instances for code clearance report on one or more selected fenestrations and data from the geospatial location circuit. In various embodiments, the performance and attribute summary report flags one or more selected fenestrations not meeting code requirements specific for the fenestration project site. However, in other embodiments, the system can be configured to prevent a system user from selecting fenestrations that do not meeting code requirements specific for a fenestration project site.

In some embodiments, the information presented through the user interface of the user input and display unit 230 can be changed based on the role of the individual using the system. This can allow a focus on information that is most relevant to an individual depending on their role. As such, in various embodiments herein, the output for the visual user interface can be configured based on a role identity of the system user. In various embodiments, the role identity can include at least one including at least one of a customer, a fenestration sales consultant, an architect, a building contractor, a building inspector, and a third-party validator.

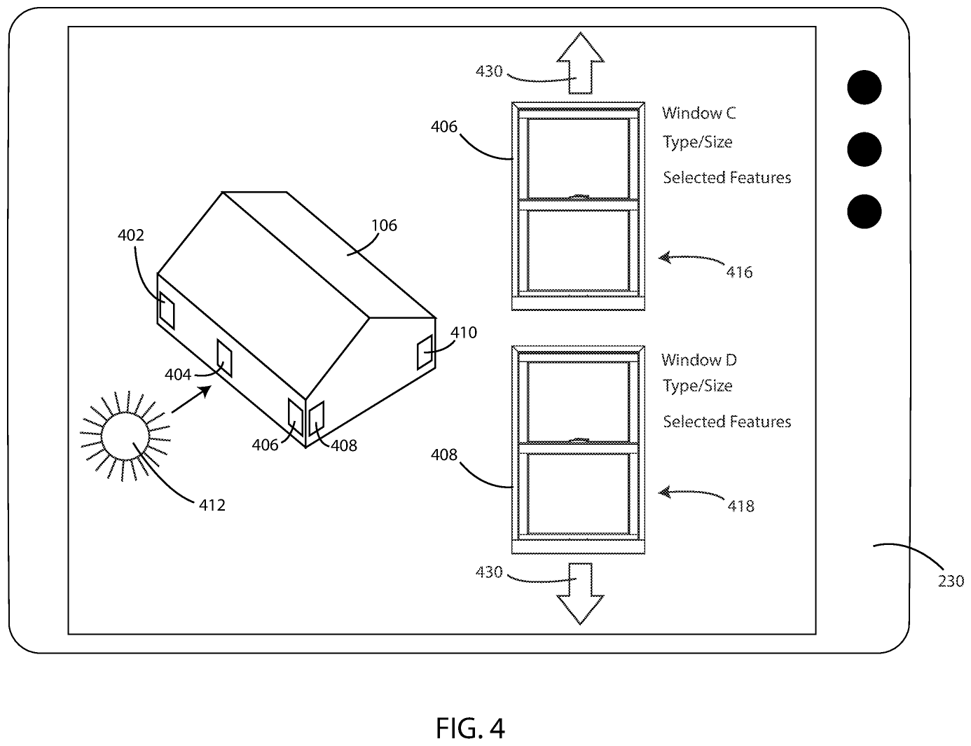

Referring now to FIG. 4, a schematic view of a user input and display unit 230 is shown in accordance with various embodiments herein. The user input and display unit 230 shows a building 106. The building 106 includes a first fenestration 402, a second fenestration 404, a third fenestration 406, a fourth fenestration 408, and a fifth fenestration 410. The fenestration project site also includes a superimposed direction 412 of highest solar exposure. Selected windows can be displayed for any of the fenestrations of the building 106. For example, selected window 416 can be shown (along with information about the same such as the type/size and selected features) as picked out for the third fenestration 406. As another example, selected window 418 can be shown (along with information about the same such as the type/size and selected features) as picked out for the fourth fenestration 408. The selected windows can be scrolled through with user interface elements 430.

In various embodiments, the fenestration product configuration system can be configured to use information regarding directionality of openings to determine the appropriate fenestrations. Such assessments can be based either on the direction of compass readings (such as determined with a system sensor herein or otherwise input) for specific openings and therefore known solar exposure conditions and/or on-site measured solar exposure and hinderance to light through local structures or foliage around the building location or a combination thereof.

In various embodiments, the fenestration product configuration system can be configured to use information regarding directionality of openings to determine an appropriate set of fenestrations (e.g., a combination of fenestrations for a fenestration project). In various embodiments, the appropriate set of fenestrations includes fenestrations differing from one another in at least one property other than fenestration size and fenestration type. In various embodiments, the appropriate set of fenestrations includes fenestrations differing from one another in at least one property relating to thermal performance. In various embodiments, the appropriate set of fenestrations includes fenestrations differing from one another in at least one property relating to light exposure such as photoactive coatings to enable facilitated cleaning, specific glass coating packages to manage energy efficiency and comfort, the use of active and passive solar harvesting technologies and/or combinations thereof.

In various embodiments, the fenestration product configuration system can be configured to only display fenestrations and/or only accept user input selection of fenestrations satisfying the applicable building code requirements.

In various embodiments, the fenestration product configuration system can be configured to estimate thermal properties of fenestrations based on in part on data from the geospatial location circuit and at least one solar-related value based on the directionality of openings for fenestrations at a particular geolocation to determine those fenestrations that are appropriate. In various embodiments, the at least one solar-related value can include at least one including at least one of solar heat gain, visual transmittance, predicted interior electric lighting needs, and interior light intensity.

In various embodiments, the fenestration product configuration system can be configured to determine recommended fenestration performance features based at least in part on data from the geospatial location circuit and positions of fenestration 108 openings at the fenestration project site 102 (e.g., the direction they are facing, their height with respect to grade, etc.). In various embodiments, the recommended fenestration performance features can include at least one including at least one of number of glass panes, glass type, presence of breather tubes and glass coatings. In some embodiments, such as with respect to the fenestrations at or below grade, recommended fenestration features can also include egress features.

In various embodiments, the fenestration product configuration system can be configured to generate data regarding costs of the recommended fenestration performance features and estimated energy savings or comfort (visual and/or thermal) of the recommended fenestration performance features and cause information regarding the same to be displayed through the visual display 234. Energy costs with respect to a fenestration can be calculated and/or estimated in various ways. Briefly, fenestrations can gain and lose heat through direct conduction and convection heat transfer through the glass or glazing and framing, through thermal radiation into and out of a structure, solar radiation into a structure which is converted to heat when absorbed by surfaces inside the structure, and air leakage through and around fenestrations. Fenestration properties with respect to these modalities of heat gain and loss can be measured and rated using parameters such as U-factor (the rate at which a fenestration transmits non-solar heat flow), solar heat gain coefficient (SHGC—the fraction of solar radiation admitted through a fenestration either transmitted directly and/or absorbed and subsequently released as heat inside a structure), and air leakage (the rate of air movement around a fenestration in the presence of a specific pressure difference across it). In some embodiments, the U-factor for a fenestration (optionally in combination with SHGC, air leakage, and/or other parameters) can be used in a calculation along with window area, temperature differences (exterior to interior), and the like to estimate energy costs associated with a fenestration.

In various embodiments, the display output circuit can be configured to generate data for a visual display 234 including a perspective view, a plan view, or other type of view of fenestrations at the fenestration project site 102 along with a superimposed direction 412 of highest solar exposure. In various embodiments, the display output circuit can be configured to display ray tracing to illustrate how sunlight will vary throughout the year at the fenestration project site 102.

In some embodiments, the system can further include a photodetector. The photodetector can generate a signal regarding light intensity at a discrete location within the fenestration project site 102. In various embodiments, the fenestration product configuration system can be further configured to determine or receive input regarding a fenestration 108 height with respect to grade.

It will be appreciated that various requirements and/or recommended features for fenestrations may have a neighborhood specific aspect. For example, homes within a particular development may share features such as stylistic features and/or fenestration performance levels. In various embodiments, the fenestration product configuration system can be configured to determine a neighborhood that the building site can be located in. This can be accomplished in various ways. In many cases, properties records can include an indication of a development or subdivision that a property may be located in. As such, in some embodiments, property records stored in a database can be referenced by way of a query issued to the relevant database and/or an API providing access to the same. In some cases, neighborhoods can be identified based on common construction dates that may be determined with reference to a property record database. In some instances, neighborhood data can be accessed through a commercial API such as that available from Zillow Group, Regrid, Cherre, and the like.

In various embodiments, the fenestration product configuration system can be configured to retrieve neighborhood-level fenestration product information and use the same to generate one or more fenestration product recommendations. Neighborhood-level fenestration product information can include, but is not limited to, stylistic information regarding the neighborhood, the age of the neighborhood, the type of fenestrations installed within the neighborhood, neighborhood-level requirements or code and the like. In some cases, the system can be configured to store information regarding fenestrations (including type, number, optional features, etc.) that are installed at each property over time. As such, the system can build and/or update a neighborhood-level fenestration product database over time.

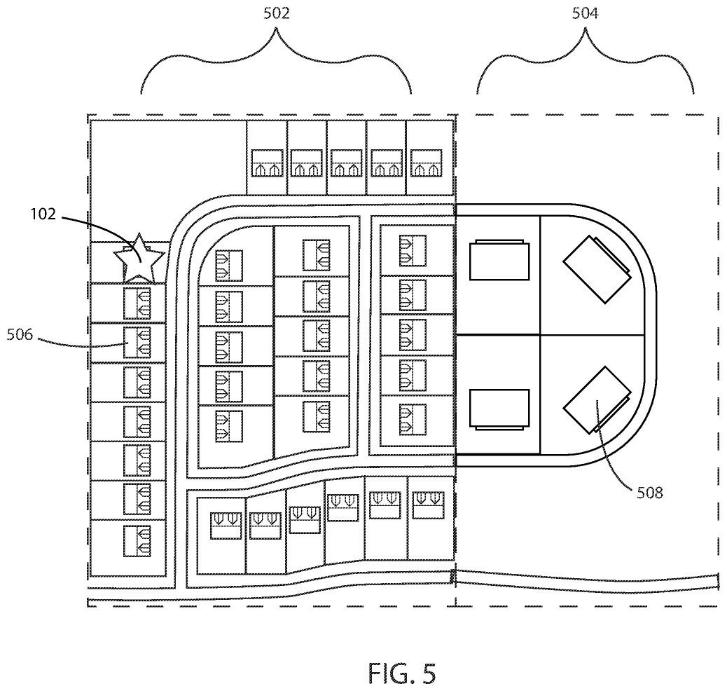

Referring now to FIG. 5, a schematic view of neighborhoods is shown in accordance with various embodiments herein. FIG. 5 shows a first neighborhood 502 with a first home type 506. FIG. 5 shows a second neighborhood 504 with a second home type 508. In this example, the fenestration project site 102 is within the first neighborhood 502. In some embodiments, the system can determine what neighborhood the fenestration project site 102 is in by using geospatial data and then cross-referencing that with a database containing neighborhood data, such as neighborhood coordinates, zones, or the like.

In various embodiments, the fenestration product configuration system can be configured to cause information regarding the neighborhood-level fenestration 108 product information to be displayed on the visual display 234. In various embodiments, the fenestration product configuration system can be configured to retrieve and display neighborhood map data 238. In various embodiments, the fenestration product configuration system can be configured to retrieve neighborhood-level fenestration 108 product style information and use the same to generate one or more fenestration 108 product style recommendations (type of window, type of grille, trim style, window shapes, mulled window combinations, etc.).

In some embodiments, neighborhood style information can be referenced for neighborhoods outside of the neighborhood in which the fenestration project site 102 is located and then used by the system in forming fenestration suggestions and/or be presented on a visual display for consideration and/or use by a system user. For example, perhaps a certain neighborhood of a community has been recently built and therefore includes recent stylistic fenestration elements (grille patterns, etc.) or a certain neighborhood is otherwise known to have desirable stylistic features (such as an area of relatively high property value). As such, the system can gather fenestration information for such neighborhoods apart from the neighborhood in which the fenestration project site is disposed and use the same in forming fenestration suggestions and/or otherwise display information regarding the same.

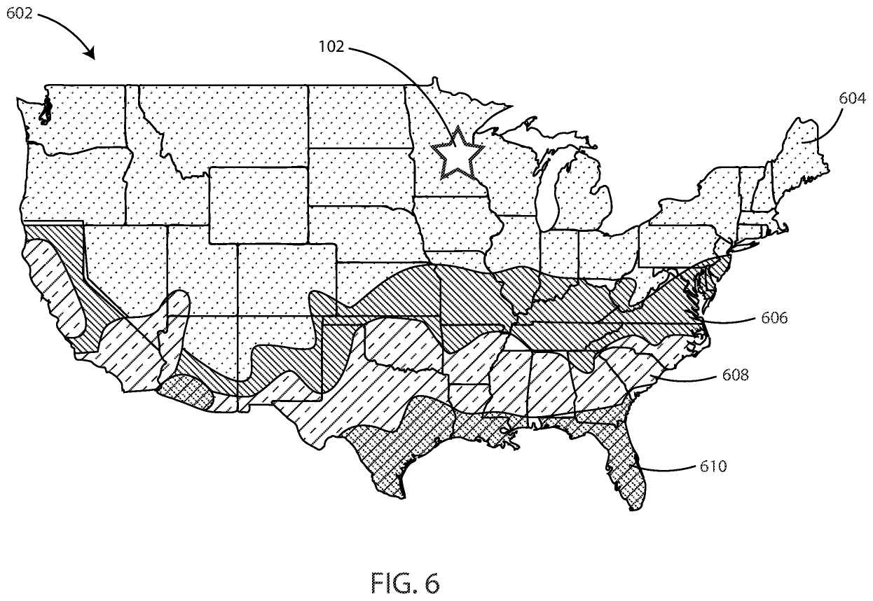

Information regarding a specific fenestration project site that is relevant for selecting appropriate fenestrations and/or fenestration feature can include climate zone data. Referring now to FIG. 6, a climate zone map 602 is shown in accordance with various embodiments herein. The climate zone map 602 includes a first zone 604, a second zone 606, a third zone 608, and a fourth zone 610. Geospatial data regarding the specific fenestration project site can be used to lookup what climate zone the fenestration project site 102 is in. In this example, the fenestration project site 102 can be within the first zone 604. In various embodiments, the fenestration product configuration system can be configured to display zone mapping impacting Energy Star ratings on the visual display 234.

In various embodiments, the fenestration product configuration system can be configured to calculate energy costs using at least one of energy rates and predominant heating types for the fenestration project site 102. For example, such information can be used in combination with data such as U-factor and other parameters as previously discussed to estimate energy costs.

Altitude data can also be significant to consider when determining appropriate fenestrations. In various embodiments, the fenestration product configuration system can be configured to determine the appropriate fenestrations for the fenestration project site 102 based in part on altitude data regarding the fenestration project site 102. In some embodiments, altitude can be measured using a system sensor. In some embodiments, data regarding altitude can be input into the system as user input.

Wind zone data can also be significant to consider when determining appropriate fenestrations. Wind zone data can be determined by reference to a database including window zone information and/or through an API providing access to the same. For example, wind zone information can be accessed through the commercially available ATC Hazards by Location public API as well as other APIs. In various embodiments, the fenestration product configuration system can be configured to determine the appropriate fenestrations for the fenestration project site 102 based in part on wind zone data regarding the fenestration project site 102.

Fire safety data can also be significant to consider when determining appropriate fenestrations. In various embodiments, the fenestration product configuration system can be configured to determine the appropriate fenestrations for the fenestration project site 102 based in part on fire safety data regarding the fenestration project site 102.

Certain types of weather, such as wind-drive rain, at the fenestration project site can also be significant to consider when determining appropriate fenestrations. In various embodiments, the fenestration product configuration system can be configured to determine the appropriate fenestrations for the fenestration project site 102 based in part on wind driven rain data regarding the fenestration project site 102. In various embodiments, the fenestration product configuration system can be configured to determine the appropriate fenestrations for the fenestration project site 102 based in part on extreme weather data specific for the fenestration project site 102 (e.g., tornado-risk at the geolocation of the fenestration project). It should be noted that these types of zones can either be defined through government or other experts and referenced by the tool through a query to a database or otherwise accessed through an API or calculated based on performance attributes by studying weather trends-such as Typical Median Year data and specific fields from that data to generate specific zones that are not universally adopted in the marketplace. In some embodiments, tornado or other hazardous weather information can be accessed through the commercially available ATC Hazards by Location public API as well as other APIs.

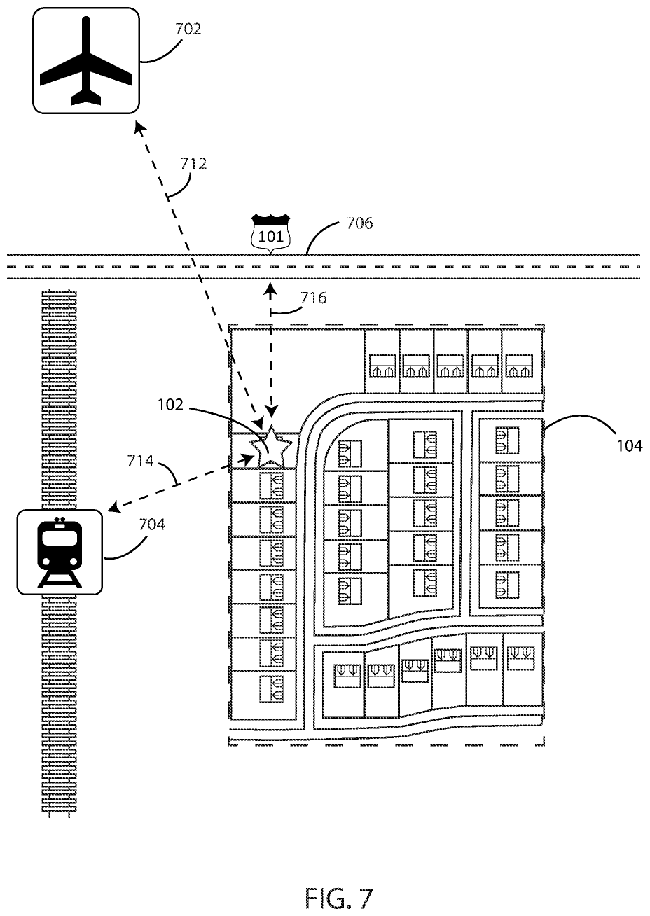

Features of fenestrations can include noise blocking and/or noise cancelling features. In various embodiments, the neighborhood data (used for calculation herein and/or for display) includes locations and/or proximities of one or more noise generating civil features. Referring now to FIG. 7, a schematic view of a neighborhood 104 and noise-generating civil features is shown in accordance with various embodiments herein. The neighborhood 104 includes a fenestration project site 102. FIG. 7 also shows noise generating civil features such as an airport 702 with proximity 712, a train track 704 with proximity 714, and a highway 706 with proximity 716. In some embodiments, the locations and/or proximities of such noise generating civil features can be determined by the system accessing a mapping-related API, such as the Google Distance Matrix API or another similar API. In various embodiments, the fenestration product configuration system can be configured to access noise data related to the fenestration project site 102 based in part on data from the geospatial location circuit and form fenestration 108 sound reduction feature recommendations based on the noise data. For example, if the system detects a noise-generating civil feature is at a distance less than a threshold value, the system can generate fenestration feature suggestions (noise mitigation features) in order to reduce the amount of noise transmitted into the interior of the structure or home. Such suggestions can be displayed by the system so that they are received by a system user.

In various embodiments, the fenestration product configuration system can be configured to access security data related to the fenestration project site 102 based in part on data from the geospatial location circuit and form fenestration security feature recommendations based on the security data. By way of example, security data related to the fenestration project site 102 can be accessed through a publicly available API, such as the Crimeometer Crime Data API, or another similar API. This information can be retrieved based on the geolocation of the fenestration project site by the system. If security data for the geolocation indicates values above a threshold value, then the system can be configured to suggest (such as through the visual display) one or more security-related fenestration features.

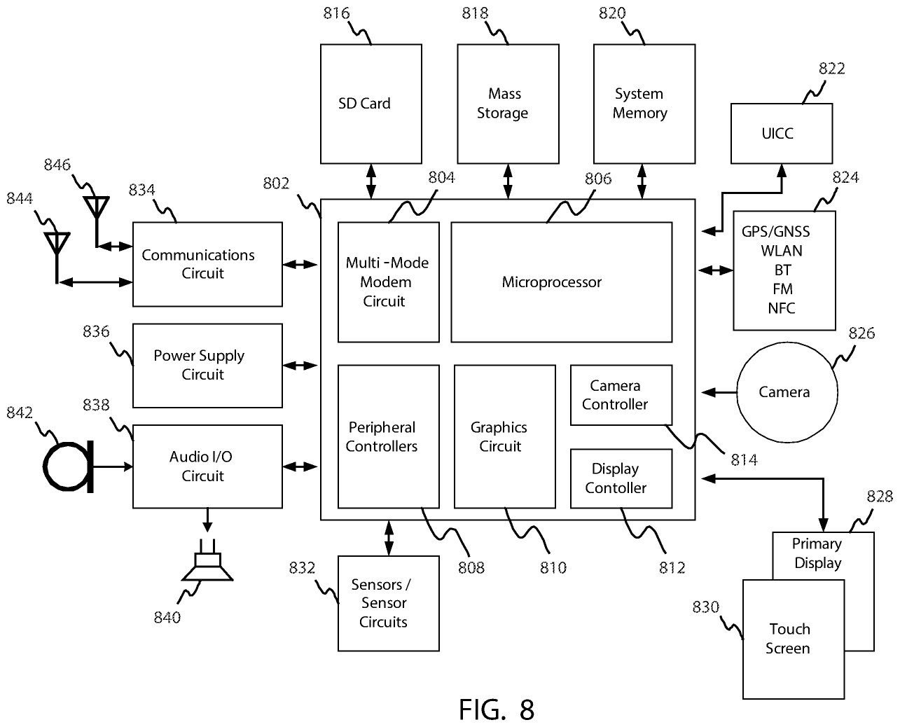

Referring now to FIG. 8, a schematic block diagram is shown of components of a system in accordance with various embodiments herein. This block diagram is just provided by way of illustration, and it will be appreciated that systems herein can include greater or lesser numbers of components (e.g., some components described can be omitted in some embodiments and other components can be added). The system in this example can include a control circuit 802. The control circuit 802 can include various components which may or may not be integrated. In various embodiments, the control circuit 802 can include a microprocessor 806, which could also be a microcontroller, FPGA, ASIC, or the like. The control circuit 802 can also include a multi-mode modem circuit 804 which can provide communications capability via various wired and wireless standards. The control circuit 802 can include various peripheral controllers 808. The control circuit 802 can also include various sensors/sensor circuits 832. Sensors herein can include, but are not limited to, temperature sensors, light sensors, photo sensors, accelerometers, a compass, altimeter, pressure sensors, and the like. The control circuit 802 can also include a graphics circuit 810 (including a GPU in some embodiments), a camera controller 814, and a display controller 812.

Graphics circuit 810 can generate a 2D or 3D image based on information including one or more of geometry, viewpoint, texture, lighting and shading information, and the like. The term “graphics pipeline” or “view rendering pipeline” can be used to refer to the sequence of steps used to create a 2D raster representation of a 3D scene. The video processing circuit and/or GPU can execute one or more steps of the graphics pipeline. The graphics circuit and/or GPU can also include one or more physical components used in the graphics pipeline. Using the information described above, the graphics pipeline can include one or more stages of creating a scene out of geometric primitives, modelling and transformation, camera transformation, lighting, projection transformation, clipping, scan conversion or rasterization, and texturing and fragment shading. In various embodiments, other operations can also be performed. In various embodiments, the graphics pipeline can use OpenGL, DirectX, or other protocols. In embodiments herein including augmented reality views, the graphics circuit and/or GPU can be used to digitally superimpose images as described herein.

In various embodiments, the control circuit 802 can interface with an SD card 816, mass storage 818, and system memory 820. In various embodiments, the control circuit 802 can interface with universal integrated circuit card (UICC) 822. A geolocation circuit or spatial location determining circuit can be included and can take the form of an integrated circuit 824 that can include components for receiving signals from GPS (such as a satellite signal receiver), GLONASS, BeiDou, Galileo, SBAS, WLAN, BT, FM, NFC type protocols, 5G picocells, or E911. In various embodiments, the system can include a camera 826. In various embodiments, the control circuit 802 can interface with a primary display 828 that can also include a touch screen 830. In various embodiments, an audio I/O circuit 838 can interface with the control circuit 802 as well as a microphone 842 and a speaker 840. In various embodiments, a power supply or power supply circuit 836 can interface with the control circuit 802 and/or various other circuits herein in order to provide power to the system. In various embodiments, a communications circuit 834 can be in communication with the control circuit 802 as well as one or more antennas (844, 846). In some embodiments, the components shown in FIG. 8 can be a part of the user input and display unit of the system described herein. In some embodiments, the components shown in FIG. 8 can be integrated as a single device. In some embodiments, the components shown in FIG. 8 can be distributed across two or more devices that are in electronic communication with one another.

In some embodiments, the system can generate one or more queries regarding building owner preferences for fenestrations. For example, the system can generate a query to gather data regarding a primary concern or interest of a building owner. In some cases, the query can be for a system user directly (such as if a homeowner is a user of the system) and in some cases the query can be for a system user to present to a relevant party (such as a homeowner). In some embodiments, the query can be presented along with a series of potential answers such as: a.) energy savings; b.) comfort; c.) letting in natural light, d.) reducing glare, etc. Other potential concerns or interests can include sustainability (as maybe reflected in fenestration aspects such as recycled material content and/or recyclability of fenestration materials used), security, and the like. An answer can be received by the system through a user input. Based on the response(s) to the query(s), the system can make appropriate recommendations regarding fenestrations meeting the primary concern or interest of the building owner. For example, after determining requirements for a fenestration at the fenestration project site, if a set of possible fenestrations all meet the minimum requirements, then the particular fenestration performing best with respect to the indicated primary concern or interest can be suggested along with data showing why it is the best choice based on that primary concern or interest. In some embodiments, the system can generate an output showing benefits (quantitative and/or qualitative) of a new fenestration or package of fenestrations with regard to the primary concern or interest of the building owner. In some embodiments, the system can be configured to accept and use information beyond a primary concern or interest and receive information regarding multiple possible concerns or interests. For example, the system can be configured to accept user input that ranks possible concerns or interest from those of most importance to those of least importance.

### Methods

Many different methods are contemplated herein, including, but not limited to, methods of making, methods of using, and the like. Aspects of system/device operation described elsewhere herein can be performed as operations of one or more methods in accordance with various embodiments herein.

In various embodiments, operations described herein and method steps can be performed as part of a computer-implemented method executed by one or more processors of one or more computing devices. In various embodiments, operations described herein and method steps can be implemented instructions stored on a non-transitory, computer-readable medium that, when executed by one or more processors, cause a system to execute the operations and/or steps.

In an embodiment, a method of determining appropriate fenestrations for a fenestration project site is included. The method can include determining and/or receiving information on appropriate fenestrations for the fenestration project site based in part on data from a geospatial location circuit and generating data for a visual display including information regarding the appropriate fenestrations.

In an embodiment, the method can further include determining a neighborhood that the building site is located in. In an embodiment, the method can further include retrieving neighborhood-level fenestration product information and using the same to generate one or more fenestration product recommendations. In an embodiment, the method can further include causing information regarding the neighborhood-level fenestration product information to be displayed on the visual display. In an embodiment, the method can further include retrieving and display neighborhood map data. In an embodiment, the method can further include retrieving neighborhood-level fenestration product style information and use the same to generate one or more fenestration product style recommendations.

In an embodiment, the method can further include determining applicable building code requirements for the fenestration project site based in part on data from the geospatial location circuit. In an embodiment, the method can further include only displaying fenestrations satisfying applicable building code requirements. In an embodiment, the method can further include causing information regarding the applicable building code requirements to be displayed on the visual display. In an embodiment, the method can further include accepting input regarding code requirements and/or other requirement values that are specific for a local area. In an embodiment, the method can further include determining outdated building code requirements for the fenestration project site based in part on data from the geospatial location circuit.

In an embodiment, the method can further include determining applicable financial incentives for fenestration features based in part on data from the geospatial location circuit and causing information regarding the applicable financial incentives to be displayed on the visual display.

In an embodiment, the method can further include displaying zone mapping impacting Energy Star ratings on the visual display.

In an embodiment, the method can further include using information regarding directionality of openings to determine the appropriate fenestrations. In an embodiment, the method can further include using information regarding directionality of openings to determine an appropriate set of fenestrations.

In an embodiment, the method can further include estimating thermal properties of fenestrations based on in part on data from the geospatial location circuit to determine those that are appropriate. In an embodiment, the method can further include estimating thermal properties of fenestrations based on in part on data from the geospatial location circuit and estimate at least one solar-related value based on the directionality of openings for fenestrations to determine those that are appropriate.

In an embodiment, the method can further include determining recommended fenestration performance features based at least in part on data from the geospatial location circuit and positions of fenestration openings at the fenestration project site.

In an embodiment, the method can further include generating data regarding costs of recommended fenestration performance features and estimated energy savings of the recommended fenestration performance features and causing information regarding the same to be displayed through the visual display.

In an embodiment, the method can further include accessing security data related to the fenestration project site based in part on data from the geospatial location circuit and forming fenestration security feature recommendations based on the security data.

In an embodiment, the method can further include accessing noise data related to the fenestration project site based in part on data from the geospatial location circuit and forming fenestration sound reduction feature recommendations based on the noise data.

In an embodiment, the method can further include generating one or more verification questions about the fenestration project site and causing them to be displayed through the visual display. In an embodiment, the method can further include generating one or more verification questions about the fenestration project site and causing them to be displayed through the visual display at a first time point prior to a site visit by a system user and generating one or more verification questions about the fenestration project site and cause them to be displayed through the visual display at a second time point during the site visit by the system user.

In an embodiment, the method can further include determining the appropriate fenestrations for the fenestration project site based in part on altitude data regarding the fenestration project site. In an embodiment, the method can further include determining the appropriate fenestrations for the fenestration project site based in part on wind zone data regarding the fenestration project site. In an embodiment, the method can further include determining the appropriate fenestrations for the fenestration project site based in part on fire safety data regarding the fenestration project site. In an embodiment, the method can further include determining the appropriate fenestrations for the fenestration project site based in part on wind driven rain data regarding the fenestration project site.

In an embodiment, the method can further include determining the appropriate fenestrations for the fenestration project site based in part on extreme weather data specific for the fenestration project site.

In an embodiment, the method can further include generating data for a visual display including a plan or perspective view of fenestrations at the fenestration project site along with a superimposed direction of highest solar exposure.

In an embodiment, the method can further include displaying ray tracing to illustrate how sunlight will vary throughout the year at the fenestration project site.

In an embodiment, the method can further include receiving user input regarding one or more selected fenestrations.

In an embodiment, the method can further include generating a code clearance report based on one or more selected fenestrations and data from the geospatial location circuit.

In an embodiment, the method can further include generating and/or receiving a signal regarding a present geolocation. In an embodiment, the method can further include receiving a signal regarding a present geolocation from a secondary device.

In an embodiment, the method can further include determining or receiving input regarding a fenestration height above grade.

In an embodiment, the method can further include calculating energy costs using at least one of energy rates and predominant heating types for the fenestration project site.

It should be noted that, as used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

It should also be noted that, as used in this specification and the appended claims, the phrase “configured” describes a system, apparatus, or other structure that is constructed or configured to perform a particular task or adopt a particular configuration. The phrase “configured” can be used interchangeably with other similar phrases such as arranged and configured, constructed and arranged, constructed, manufactured and arranged, and the like.

All publications and patent applications in this specification are indicative of the level of ordinary skill in the art to which this invention pertains. All publications and patent applications are herein incorporated by reference to the same extent as if each individual publication or patent application was specifically and individually indicated by reference.

As used herein, the recitation of numerical ranges by endpoints shall include all numbers subsumed within that range (e.g., 2 to 8 includes 2.1, 2.8, 5.3, 7, etc.).

The headings used herein are provided for consistency with suggestions under 37 CFR 1.77 or otherwise to provide organizational cues. These headings shall not be viewed to limit or characterize the invention(s) set out in any claims that may issue from this disclosure. As an example, although the headings refer to a “Field,” such claims should not be limited by the language chosen under this heading to describe the so-called technical field. Further, a description of a technology in the “Background” is not an admission that technology is prior art to any invention(s) in this disclosure. Neither is the “Summary” to be considered as a characterization of the invention(s) set forth in issued claims.

The embodiments described herein are not intended to be exhaustive or to limit the invention to the precise forms disclosed in the following detailed description. Rather, the embodiments are chosen and described so that others skilled in the art can appreciate and understand the principles and practices. As such, aspects have been described with reference to various specific and preferred embodiments and techniques. However, it should be understood that many variations and modifications may be made while remaining within the spirit and scope herein.

1. A fenestration product configuration system comprising:
a control circuit;
a geospatial location circuit, wherein the geospatial location circuit is in signal communication with the control circuit; and
a display output circuit, wherein the display output circuit is in signal communication with the control circuit;
wherein the fenestration product configuration system is configured to determine and/or receive information on appropriate fenestrations for a fenestration project site based in part on data from the geospatial location circuit; and
wherein the display output circuit is configured to generate data for a visual display including information regarding the appropriate fenestrations.

2. (canceled)

3. The fenestration product configuration system of claim 1, wherein the fenestration product configuration system is configured to retrieve neighborhood-level fenestration product information and use the same to generate one or more fenestration product recommendations.

4. (canceled)

5. The fenestration product configuration system of claim 1, wherein the fenestration product configuration system is configured to retrieve and display neighborhood map data.

6. The fenestration product configuration system of claim 1, wherein the neighborhood map data includes locations of one or more noise generating civil features.

7. The fenestration product configuration system of claim 1, wherein the fenestration product configuration system is configured to retrieve neighborhood-level fenestration product style information and use the same to generate one or more fenestration product style recommendations.

8. The fenestration product configuration system of claim 1,
wherein the fenestration product configuration system is configured to determine applicable building code requirements for the fenestration project site based in part on data from the geospatial location circuit; and
wherein the appropriate fenestrations are selected including reference to the applicable building code requirements.

9-10. (canceled)

11. The fenestration product configuration system of claim 1, wherein the fenestration product configuration system is configured to accept input regarding code requirements and/or other requirement values that are specific for a local area.

12-15. (canceled)

16. The fenestration product configuration system of claim 1, wherein the fenestration product configuration system is configured to display zone mapping impacting Energy Star ratings on the visual display.

17. (canceled)

18. The fenestration product configuration system of claim 1, wherein the fenestration product configuration system is configured to use information regarding directionality of openings to determine an appropriate set of fenestrations.

19. The fenestration product configuration system of claim 1, wherein the appropriate set of fenestrations includes fenestrations differing from one another in at least one property other than fenestration size and fenestration type.

20-21. (canceled)

22. The fenestration product configuration system of claim 1, wherein the fenestration product configuration system is configured to estimate thermal properties of fenestrations based on in part on data from the geospatial location circuit and estimate at least one solar-related value based on the directionality of openings for fenestrations to determine those that are appropriate.

23. (canceled)

24. The fenestration product configuration system of claim 1, wherein the fenestration product configuration system is configured to determine recommended fenestration performance features based at least in part on data from the geospatial location circuit and positions of fenestration openings at the fenestration project site.

25-26. (canceled)

27. The fenestration product configuration system of claim 1, wherein the fenestration product configuration system is configured to access security data related to the fenestration project site based in part on data from the geospatial location circuit and form fenestration security feature recommendations based on the security data.

28. The fenestration product configuration system of claim 1, wherein the fenestration product configuration system is configured to access noise data related to the fenestration project site based in part on data from the geospatial location circuit and form fenestration sound reduction feature recommendations based on the noise data.

29. The fenestration product configuration system of claim 1, wherein the noise data includes one or more noise generating civil features.

30-31. (canceled)

32. The fenestration product configuration system of claim 1, wherein the fenestration product configuration system is configured to generate one or more verification questions about the fenestration project site and cause them to be displayed through the visual display at a first time point prior to a site visit by a system user and generate one or more verification questions about the fenestration project site and cause them to be displayed through the visual display at a second time point during the site visit by the system user.

33. The fenestration product configuration system of claim 1, wherein the fenestration product configuration system is configured to determine the appropriate fenestrations for the fenestration project site based in part on altitude data regarding the fenestration project site.

34. The fenestration product configuration system of claim 1, wherein the fenestration product configuration system is configured to determine the appropriate fenestrations for the fenestration project site based in part on wind zone data regarding the fenestration project site.

35-40. (canceled)

41. The fenestration product configuration system of claim 1, wherein the display output circuit is configured to generate data for a visual display including a plan or perspective view of fenestrations at the fenestration project site along with a superimposed direction of highest solar exposure.

42. (canceled)

43. The fenestration product configuration system of claim 1, further comprising a photodetector;
wherein the photodetector is in electronic communication with the control circuit; and
wherein the photodetector generates a signal regarding light intensity at a discrete location within the fenestration project site.

44-87. (canceled)
